(19) United States
(12) Patent Application Publication
(10) Pub. No.: US 2026/0168098 A1
(43) Pub. Date: Jun. 18, 2026

(54) PRECURSOR SUPPLY SYSTEM AND APPARATUS FOR SEMICONDUCTOR MANUFACTURING

(71) Applicant: Samsung Electronics Co., Ltd., Suwon-si (KR)

(72) Inventors: Sejin PARK, Suwon-si (KR); Sangyoon SOH, Suwon-si (KR)

(21) Appl. No.: 19/231,502

(22) Filed: Jun. 8, 2025

(30) Foreign Application Priority Data
Dec. 16, 2024 (KR) 10-2024-0187482

(51) Int. Cl. C23C 16/455; C23C 16/52; H01L 21/67

(52) U.S. Cl. CPC C23C 16/45561; C23C 16/52; H10P 72/0402

(57) ABSTRACT

A precursor supply system includes a precursor supply apparatus for containing a precursor, a fluid tank for containing a fluid, a precursor supply line connected to the precursor supply apparatus, and including an inner pipe configured to allow the precursor to flow therein, and a first outer pipe spaced apart from the inner pipe and disposed to surround the inner pipe, a fluid supply line connected to the first outer pipe and configured to allow the fluid to flow therein from the fluid tank to the first outer pipe, and a fluid recovery line connected to the first outer pipe and configured to allow the fluid to flow therein from the first outer pipe to the fluid tank, in which the fluid flowing along the fluid supply line flows through a first space formed between the first outer pipe and the inner pipe.

### CROSS-REFERENCE TO RELATED APPLICATION

This application claims priority under 35 U.S.C. § 119 to Korean Patent Application No. 10-2024-0187482, filed in the Korean Intellectual Property Office on Dec. 16, 2024, the entire contents of which are hereby incorporated by reference.

### BACKGROUND

### Field

The present disclosure relates to a precursor supply system and an apparatus for semiconductor manufacturing including the same.

### Description of Related Art

Materials (e.g., raw material gas, etc.) used in the semiconductor manufacturing process may be moved to various devices along pipes. These pipes are generally exposed to an environment at room temperature and the materials moving along the pipes may exchange heat with air that is external to the pipe. Accordingly, the temperature of the materials entering the pipes may be subject to variation. If these materials are not supplied with a constant temperature for use in the semiconductor manufacturing process, they may cause a disruption in the semiconductor manufacturing process or a problem in the corresponding pipes. Therefore, it may be required to keep the temperature of the materials moving along the pipes constant.

The information described above is intended to improve understanding of the background of the present disclosure, and may include information that does not constitute the related art.

### SUMMARY

In order to solve one or more problems (e.g., the problems described above and/or other problems not explicitly described herein), the present disclosure provides a precursor supply system and an apparatus for semiconductor manufacturing capable of improving the reliability of a semiconductor manufacturing process.

In order to solve one or more problems (e.g., the problems described above and/or other problems not explicitly described herein), the present disclosure provides a precursor supply system and an apparatus for semiconductor manufacturing capable of maintaining a temperature of a precursor, fluid, etc. flowing for use in a semiconductor manufacturing process.

The object to be achieved by the present disclosure is not limited to the above, and other objects not explicitly described herein may be clearly understood by those skilled in the art from the description and the present diagrams.

A precursor supply system is provided, which may include a precursor supply apparatus for containing a precursor, a fluid tank for containing a fluid, a precursor supply line connected to the precursor supply apparatus, and including an inner pipe configured to allow the precursor to flow therein, and a first outer pipe spaced apart from the inner pipe and disposed to surround the inner pipe, a fluid supply line connected to the first outer pipe and configured to allow the fluid to flow therein from the fluid tank to the first outer pipe, and a fluid recovery line connected to the first outer pipe and configured to allow the fluid to flow therein from the first outer pipe to the fluid tank, in which the fluid flowing along the fluid supply line may flow through a first space formed between the first outer pipe and the inner pipe.

According to some aspects, an apparatus for semiconductor manufacturing is provided, which may include a first fluid supply apparatus for containing a first fluid, a second fluid supply apparatus for containing a second fluid, a reaction chamber configured to be supplied with the first fluid therein, a multilayer pipe that may connect the first fluid supply apparatus to the reaction chamber and may include an inner pipe configured to allow the first fluid to flow from the first fluid supply apparatus to the reaction chamber, and a first outer pipe spaced apart from the inner pipe in an outward direction and having the inner pipe disposed therein, a fluid supply line merging into the first outer pipe and configured to allow the second fluid to flow from the second fluid supply apparatus to the first outer pipe, a fluid recovery line branched off from the first outer pipe and configured to allow the second fluid to flow from the first outer pipe to the second fluid supply apparatus, and a heater configured to heat the second fluid contained in the second fluid supply apparatus, in which the second fluid may flow sequentially along the fluid supply line, between the first outer pipe and the inner pipe, and along the fluid recovery line.

According to some aspects, an apparatus for semiconductor manufacturing is provided, which may include a precursor supply apparatus for containing a precursor, a fluid tank for containing a fluid, a reaction chamber configured to be supplied with the precursor therein and perform a process for semiconductor manufacturing using the precursor, a precursor supply line connected to the precursor supply apparatus, and including an inner pipe configured to allow the precursor to flow therein, and a first outer pipe spaced apart from the inner pipe and disposed to surround the inner pipe, a fluid supply line connected to the first outer pipe and configured to allow the fluid to flow therein from the fluid tank to the first outer pipe, a fluid recovery line connected to the first outer pipe and configured to allow the fluid to flow therein from the first outer pipe to the fluid tank, a first temperature sensor configured to sense a temperature of the fluid flowing along the fluid supply line and output a first temperature value, a second temperature sensor configured to sense a temperature of the fluid flowing along the fluid recovery line and output a second temperature value, a third temperature sensor configured to sense a temperature of the fluid contained in the fluid tank and output a third temperature value, a pump configured to supply the fluid contained in the fluid tank to the fluid supply line, a heater configured to heat the fluid contained in the fluid tank, and a controller configured to receive the first temperature value, the second temperature value, and the third temperature value and control at least one of the pump or the heater, in which the fluid flowing along the fluid supply line may flow between the first outer pipe and the inner pipe.

According to various aspects of the present disclosure, it is possible to maintain the fluidity of the precursor so as not to block the inner pipe, to reduce the possibility of damage to the inner pipe, and to prevent unnecessary costs.

According to various aspects of the present disclosure, the precursor having a predetermined temperature range can be supplied to the reaction chamber, thereby improving the quality consistency and reducing a defect rate of the semiconductors manufactured in the reaction chamber.

The effects obtained through the present disclosure are not limited to those described above. Technical effects not mentioned herein will be clearly understood by those skilled in the art from the description of the present disclosure described below.

### BRIEF DESCRIPTION OF THE DRAWINGS

The above and other objects, features and advantages of the present disclosure will become more apparent to those of ordinary skill in the art by describing in detail exemplary embodiments thereof with reference to the accompanying drawings, in which:

FIG. 1 is a schematic diagram provided to explain an example apparatus for semiconductor manufacturing;

FIG. 2 is a diagram illustrating an example of a precursor supply system;

FIG. 3 is a side cross-sectional view of an example of a precursor supply line;

FIG. 4 is a side cross-sectional view of an example of a precursor supply line;

FIG. 5 is a cross-sectional view of an example of a precursor supply line;

FIG. 6 is a cross-sectional view of an example of a precursor supply line;

FIG. 7 is a cross-sectional view of an example of a precursor supply line;

FIG. 8 is a view illustrating an example of a precursor supply line and a fluid recovery line;

FIG. 9 shows cross-sectional views of an example of a precursor supply line and a fluid recovery line;

FIG. 10 shows cross-sectional views of an example of a precursor supply line, a fluid recovery line, and a third outer pipe;

FIG. 11 is a flowchart provided to explain an example of a method for controlling at least one of a pump and a heater;

FIG. 12 is a flowchart provided to explain an example of a method for controlling at least one of a pump and a heater;

FIG. 13 is a flowchart provided to explain an example of a method for outputting an alert associated with fluid leakage;

FIG. 14 is a schematic diagram provided to explain a manufacturing apparatus; and

FIG. 15 shows simulation data of a fluid flowing between a first outer pipe and an inner pipe.

### DETAILED DESCRIPTION

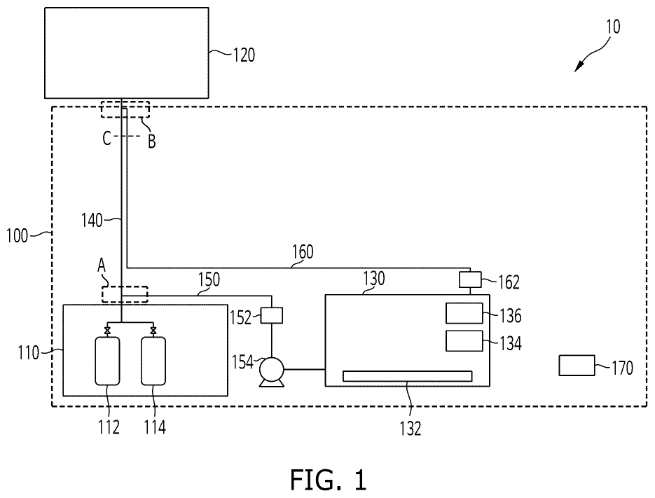

Hereinafter, various aspects of the present disclosure will be described with reference to FIGS. 1 to 15. Throughout the description, the same reference numerals refer to the same components.

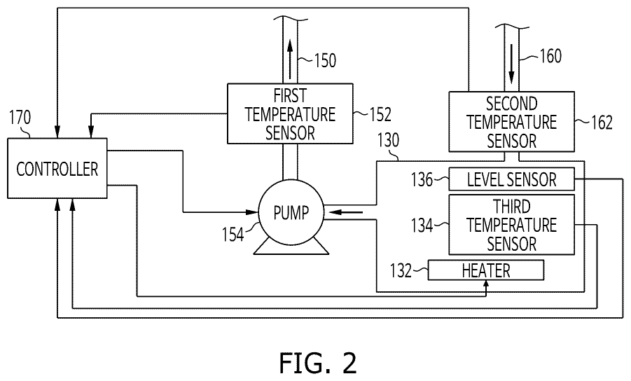

FIG. 1 is a schematic diagram illustrating an apparatus 10 for semiconductor manufacturing. FIG. 2 is a diagram illustrating an example of a precursor supply system 100.

The apparatus 10 for semiconductor manufacturing may include the precursor supply system 100 and a reaction chamber 120. The precursor supply system 100 may include a precursor supply apparatus 110 configured to receive a precursor and supply the precursor to the reaction chamber 120. In addition, the precursor supply system 100 may include a precursor supply line 140 connected to the precursor supply apparatus 110. The precursor supply line 140 may be a multilayer pipe including an inner pipe and an outer pipe. The inner pipe may be configured to allow precursor flow therein. The inner pipe may be sealed internally, except for both ends thereof, such that the precursor supplied from the precursor supply apparatus 110 may flow between both ends of the inner pipe. For example, the precursor of the precursor supply apparatus 110 may be supplied to the reaction chamber 120 through the precursor supply line 140.

The precursor supply apparatus 110 may contain precursors in gaseous, liquid, and/or solid states. For example, the precursor supply apparatus 110 may generate the precursors from liquid and/or solid states into gaseous and/or liquid states. The precursor supply apparatus 110 may supply the precursors in gaseous and/or liquid states to the inner pipe of the precursor supply line 140.

The precursor supply apparatus 110 may include a first precursor tank 112 containing at least some of the precursors and a second precursor tank 114 containing at least some other precursors. In other words, the precursors included in the first precursor tank 112 and the second precursor tank 114 may be the same material. The first precursor tank 112 and/or the second precursor tank 114 may be connected to the precursor supply line 140. For example, the precursor contained in the first precursor tank 112 may be first supplied to the precursor supply line 140. At this time, the supply of the precursor contained in the second precursor tank 114 may be blocked. If the precursors in the first precursor tank 112 are depleted or mostly depleted, the supply of the precursor contained in the first precursor tank 112 may be blocked, and the precursor contained in the second precursor tank 114 may be supplied to the precursor supply line 140. In this case, the first precursor tank 112 may be replaced with another precursor tank that contains precursors.

The first precursor tank 112 and/or the second precursor tank 114 may include a heater. The precursors in solid state contained in the first precursor tank 112 and/or the second precursor tank 114 may be sublimated or liquefied by the heater, or the precursors in liquid state may be vaporized.

A process for manufacturing a semiconductor may be performed in the reaction chamber 120 using the supplied precursors. For example, the precursors may induce, trigger, and/or participate in a chemical reaction in at least some of the processes of semiconductor manufacturing. For example, the precursors may include a molybdenum (Mo) precursor. The precursors supplied into the reaction chamber 120 may be deposited on a substrate forming the semiconductor by Chemical Vapor Deposition (CVD) method, Atomic Layer Deposition (ALD) method, etc.

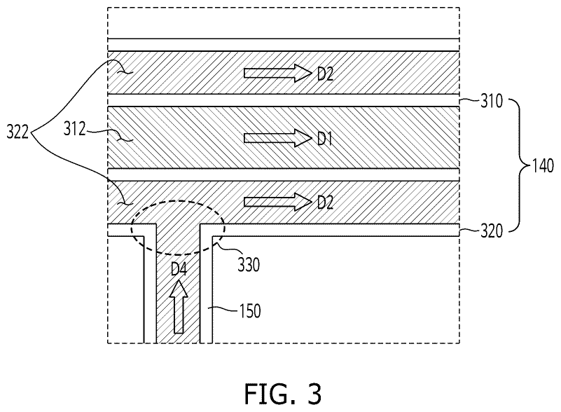

The precursor supply line 140 may be connected to the precursor supply apparatus 110 and include the inner pipe configured to allow the precursor to flow therein, and a first outer pipe spaced apart from the inner pipe and configured to surround the inner pipe. The structures of the inner pipe and the first outer pipe included in the precursor supply line 140 will be described in detail with reference to FIGS. 3 to 7.

The precursor supply system 100 may include a fluid tank 130, a fluid supply line 150 connected to the first outer pipe of the precursor supply line 140 and configured to allow a fluid to flow from the fluid tank 130 to the first outer pipe of the precursor supply line 140, and a fluid recovery line 160 connected to the first outer pipe of the precursor supply line 140 and configured to allow a fluid to flow from the first outer pipe of the precursor supply line 140 to the fluid tank 130. The fluid may flow along the fluid supply line 150 and between the first outer pipe and the inner pipe. The fluid flowing between the first outer pipe and the inner pipe may maintain the temperature of the precursor flowing inside the inner pipe to be constant or within a certain range.

The fluid may contain materials with high fluidity, low reactivity, and high heat capacity. For example, the fluid may include at least one of silicone oil, water vapor, mineral oil, or synthetic oil. However, aspects are not limited thereto.

The fluid contained in the fluid tank 130 may sequentially flow along the fluid supply line 150, between the first outer pipe and the inner pipe, and along the fluid recovery line 160. In addition, the fluid along the fluid recovery line 160 may flow back to the fluid tank 130 and be contained in the fluid tank 130. Thus, a fluid circulation and regeneration system may be established.

The precursor supply system 100 may include a pump 154 configured to supply the fluid contained in the fluid tank 130 to the fluid supply line. Although not illustrated in FIG. 1, the precursor supply system 100 may further include a pump configured to supply the fluid supplied to a fluid discharge line to the fluid tank 130. Additionally, the precursor supply system 100 may further include a valve configured to close or open the fluid supply line 150 for the fluid flowing therethrough and/or a valve configured to close or open the fluid recovery line 160 for the fluid flowing therethrough.

In FIG. 1, the lower portion may indicate a direction of gravity, while the upper portion may indicate a direction contrary to gravity. That is, the precursor supply system 100 may be positioned below the reaction chamber 120 with respect to the direction of gravity. For example, the precursor supply apparatus 110 and the fluid tank 130 may be positioned below the reaction chamber 120 based on the direction of gravity. In this case, the pump 154 may supply the fluid against the direction of gravity to the inner pipe of the fluid supply line 150 and/or the precursor supply line 140. In addition, the fluid supplied to the fluid recovery line 160 may be supplied to the fluid tank 130 along the fluid recovery line 160 by gravity and/or by external force such as pump. However, as illustrated in FIG. 1, positions of the components are not limited.

A first connection between the fluid supply line 150 and the first outer pipe of the precursor supply line 140 may be positioned adjacent to the precursor supply apparatus 110. A second connection between the fluid recovery line 160 and the first outer pipe may be positioned adjacent to the reaction chamber 120. For example, the first connection may be positioned closer to the precursor supply apparatus 110 than the second connection. The first connection may be positioned in a boxed area A of FIG. 1, and the second connection may be positioned in a boxed area B of FIG. 1. Accordingly, the fluid may flow from the precursor supply apparatus 110 toward the reaction chamber 120 through the first outer pipe and the inner pipe.

The precursor supply system 100 may include a heater 132 configured to heat the fluid contained in the fluid tank 130. The temperature of the fluid flowing between the first outer pipe and the inner pipe may be higher than or substantially the same as the temperature of the precursor flowing inside the inner pipe so as to maintain the temperature of the precursor flowing inside the inner pipe. To this end, the heater 132 may heat the fluid contained in the fluid tank 130 so as to increase the temperature of the fluid supplied between the first outer pipe and the inside.

The precursor supply system 100 may include a level sensor 136 configured to sense the level of the fluid contained in the fluid tank 130 and output a level value. The fluid contained in the fluid tank 130 may have a level associated with an amount of fluid. For example, the fluid tank 130 may have liquid fluid with a height as the level of the fluid. In this case, the level sensor 136 may sense the level of the fluid and output the level value.

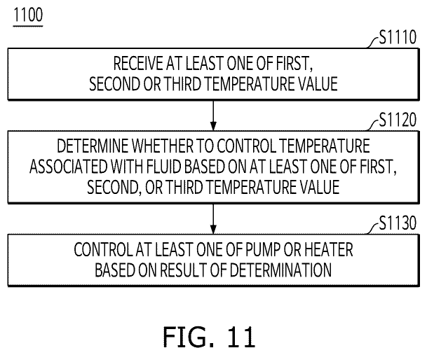

The precursor supply system 100 may include a plurality of temperature sensors disposed at different positions. The precursor supply system 100 may include a first temperature sensor 152 configured to sense the temperature of the fluid flowing along the fluid supply line 150 to output a first temperature value, a second temperature sensor 162 configured to sense the temperature of the fluid flowing along the fluid recovery line 160 to output a second temperature value, and a third temperature sensor 134 configured to sense the temperature of the fluid contained in the fluid tank 130 to output a third temperature value. In addition, the precursor supply system 100 may include a controller 170 configured to receive at least one of the first temperature value, the second temperature value, the third temperature value, or the level value. The controller 170 may be configured to control at least one of the pump 154 or the heater 132. For example, the controller 170 may control at least one of the pump 154 or the heater 132 based on at least one of the first temperature value, the second temperature value, or the level value. The process performed in the controller 170 will be described in detail with reference to FIGS. 11 to 13.

The controller 170 may include a memory and/or a processor. The memory may include any non-transitory computer readable medium. The memory may include a permanent mass storage device such as Random Access Memory (RAM), Read Only Memory (ROM), disk drive, Solid State Drive (SSD), and flash memory. As another example, a non-extinguishable mass storage device such as a ROM, an SSD, a flash memory, a disk drive may be included in the controller 170 as a separate permanent storage device separate from the memory. In addition, the memory may store an operating system and at least one program code (e.g., a code that controls the pump 154 or the heater 132 installed and driven in the controller 170.

The processor may be configured to process data, control signals, and/or commands of a computer program by performing basic arithmetic, logic, and input and output operations. The data, control signals, and/or commands may be provided by a memory or a communication module to a sensor (e.g., the first temperature sensor 152, the second temperature sensor 162, the third temperature sensor 134, the level sensor 136, etc.), an external device (e.g., the pump 154, the heater 132, etc.), or other external system. For example, the processor may control at least one of the pump 154 or the heater 132 based on at least one of the first temperature value, the second temperature value, or the third temperature value.

Additionally, the controller 170 may further include the communication module. The communication module may provide a configuration or function for communication with a charging device, and the controller 170 may provide a configuration or function for communication with the external device, the external system, etc. For example, control signals, commands, data, etc. provided under the control of the processor of the controller 170 may be transmitted through the communication module to the sensor, the external device and/or the external system through the communication module of the sensor, the external device and/or the external system.

The temperature of the precursor flowing along the precursor supply line 140 may be maintained at a constant temperature or within a certain range of temperatures. For example, the precursor flowing through the inner pipe may be maintained at a constant temperature by the heat transferred from the fluid flowing between the first outer pipe and the inner pipe. For example, the precursor flowing along the inner pipe of the precursor supply line 140 may be maintained at about 160 degrees Celsius. The fluid flowing in contact with an outer surface of the inner pipe may be about 160 degrees Celsius to 180 degrees Celsius. In this case, it may be easy to maintain the precursor flowing along the inner pipe at about 160 degrees Celsius.

If the temperature of the precursor flowing through the inner pipe is relatively low, its reduced fluidity may cause blockages in the inner pipe. If the temperature of the precursor flowing through the inner pipe is relatively high, the pressure of the precursor supply line and/or the inner pipe increases, possibly damaging the precursor supply line and/or the inner pipe. Additionally, applying heat to maintain a relatively high temperature of the precursor flowing through the inner pipe may incur unnecessary costs. In addition, the precursors with relatively high temperature may adversely affect the quality or yield of semiconductors to be manufactured.

The precursor supply system 100 and/or the apparatus 10 for semiconductor manufacturing may maintain the fluidity of the precursor so as not to block the inner pipe, reduce the possibility of damage to the inner pipe, and prevent unnecessary costs. In addition, maintaining the temperature of the pipe with the heating wire requires a considerable space for the controller of the heating wire, but the precursor supply system 100 and/or the apparatus 10 for semiconductor manufacturing according to some aspects may be implemented in a relatively small space.

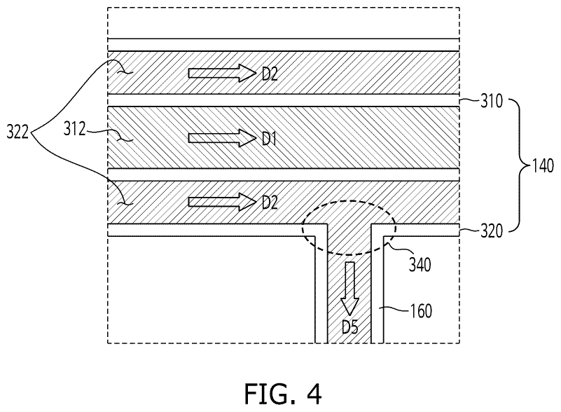

FIG. 3 is a side cross-sectional view of an example of the precursor supply line 140. FIG. 4 is a side cross-sectional view of an example of the precursor supply line 140. FIG. 3 may illustrate a side cross-section of the boxed area A of the precursor supply line 140 of FIG. 1, and FIG. 4 may illustrate a side cross-section of another boxed area B of the precursor supply line 140 of FIG. 1.

Referring to FIG. 3, the fluid supply line 150 may merge into a first outer pipe 320 of the precursor supply line 140. A first connection 330 may connect the fluid supply line 150 and the first outer pipe 320 of the precursor supply line 140. The fluid supplied along the fluid supply line 150 may be supplied to a first space 322 between the first outer pipe 320 and an inner pipe 310 through the first connection 330. For example, fluid supplied along the fluid supply line 150 may enter the first space 322 in a vertical direction (e.g., in a direction D4) of the precursor supply line 140. The space in the fluid supply line 150 may communicate with the first space 322 through the first connection 330.

Referring to FIG. 4, the fluid recovery line 160 may be branched off from the first outer pipe 320 of the precursor supply line 140. A second connection 340 may connect a fluid recovery line 156 and the first outer pipe 320 of the precursor supply line 140. The fluid flowing through the first space 322 between the first outer pipe 320 and the inner pipe 310 may be supplied to the fluid recovery line 160 through the second connection 340. For example, the fluid flowing along the first space 322 may be discharged to the fluid recovery line 160 in a vertical direction (e.g., a direction D5) of the precursor supply line 140. The first space 322 and a space within the fluid recovery line 160 may communicate with each other through the second connection 340.

The precursor may flow through an inner space 312 of the inner pipe 310 in a direction (e.g., in a direction D1) from the precursor supply apparatus (e.g., precursor supply apparatus 110 of FIG. 2) to the reaction chamber (e.g., reaction chamber 120 of FIG. 2). The fluid may flow through the first space 322 between the first outer pipe 320 and the inner pipe 310 in a direction (e.g., in a direction D2) from the precursor supply apparatus (e.g., precursor supply apparatus 110 of FIG. 2) to the reaction chamber (e.g., reaction chamber 120 of FIG. 2). For example, by the pressure of the fluid supplied along the fluid supply line 150, the fluid positioned in the first space 322 may flow in the direction from the precursor supply apparatus (e.g., precursor supply apparatus 110 of FIG. 2) to the reaction chamber (e.g., reaction chamber 120 of FIG. 2). That is, a flow direction of the fluid flowing inside the precursor supply line 140 and a flow direction of the precursor may be substantially the same.

As described above, the fluid flowing through the first space 322 may be in contact with the outer circumference of the inner pipe 310, thereby maintaining a constant temperature inside the inner pipe 310. Accordingly, the temperature of the precursor flowing through the inner space 312 of the inner pipe 310 may be maintained at a constant temperature.

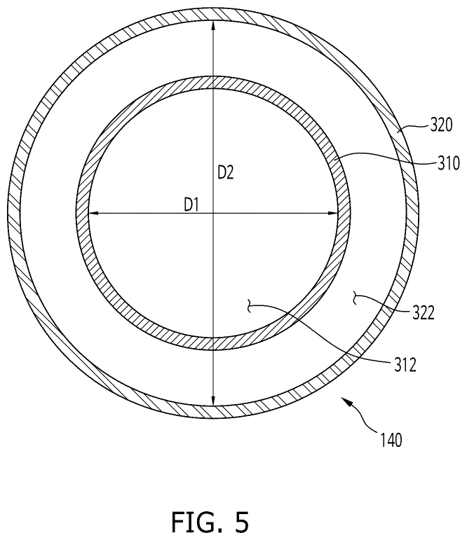

FIG. 5 is a cross-sectional view of an example of the precursor supply line 140. FIG. 5 is the cross-sectional view of the precursor supply line 140, which may show a cross-section of the inner pipe 310 and a cross-section of the first outer pipe 320. The inner space 312 of the inner pipe 310 may be a passage through which the precursor flows, and the first space 322 between the inner pipe 310 and the first outer pipe 320 may be a passage through which the fluid flows.

The inner pipe 310 and the first outer pipe 320 may include at least one of stainless steel (STS) and hastelloy. For example, the inner pipe 310 and the first outer pipe 320 may include at least one of STS 304, STS 316, and hastelloy.

Referring to FIG. 5, the cross-section of the inner pipe 310 and the cross-section of the first outer pipe 320 may be approximately circular. A diameter D2 of the cross-section of the first outer pipe 320 may be 1.5 to 2 times a diameter D1 of the cross-section of the inner pipe 310. For example, the diameter of the cross-section of the inner pipe 310 may be about ¾ inches, and the diameter of the first outer pipe 320 may be about 5/4 inches, but aspects are not limited thereto.

Although it is illustrated that centers of the inner pipe 310 and the first outer pipe 320 coincide with each other, aspects are not limited thereto, and it is sufficient if the inner pipe 310 is disposed inside the first outer pipe 320. The diameter is shown as the diameter of the inner circumference of the pipe, but may also indicate the diameter of the outer circumference.

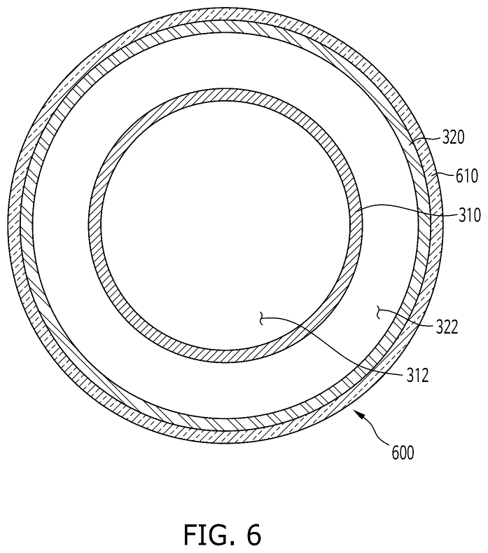

FIG. 6 is a cross-sectional view of an example of a precursor supply line 600. The precursor supply line 600 may correspond to the precursor supply line 140 of FIGS. 1 to 4. For example, precursor may flow through an inner space 312 of the inner pipe 310 of the precursor supply line 600 from the precursor supply apparatus 110 to the reaction chamber 120. In addition, fluid may be supplied along the fluid supply line 150 to a first space 322 between the first outer pipe 320 and an inner pipe 310 of the precursor supply line 600 through the first connection 330, and fluid may flow through the first space 322 between the first outer pipe 320 and the inner pipe 310 of the precursor supply line 600 to be supplied to the fluid recovery line 160 through the second connection 340.

The precursor supply line 600 may include a thermal insulation layer 610 surrounding at least a portion of the outer circumference of the precursor supply line 600. For example, the thermal insulation layer 610 may include at least one of silica wool, mineral wool, or aerogel as the thermal insulating material.

The precursor supply line 600 may be disposed in the environment at room temperature. In this case, the thermal insulation layer 610 may reduce or prevent heat from being exchanged through the outer circumference of the first outer pipe 320. Accordingly, the thermal insulation layer 610 may help to maintain a constant temperature of the fluid flowing through the first space 322 between the inner pipe 310 and the first outer pipe 320.

As described above, the fluid flowing through the first space 322 may be in contact with the outer circumference of the inner pipe 310. By maintaining a constant temperature of the fluid flowing through the first space 322, a constant temperature may be maintained inside the inner pipe 310. Accordingly, the temperature of the precursor flowing through the inner space 312 of the inner pipe 310 may be maintained at a constant temperature.

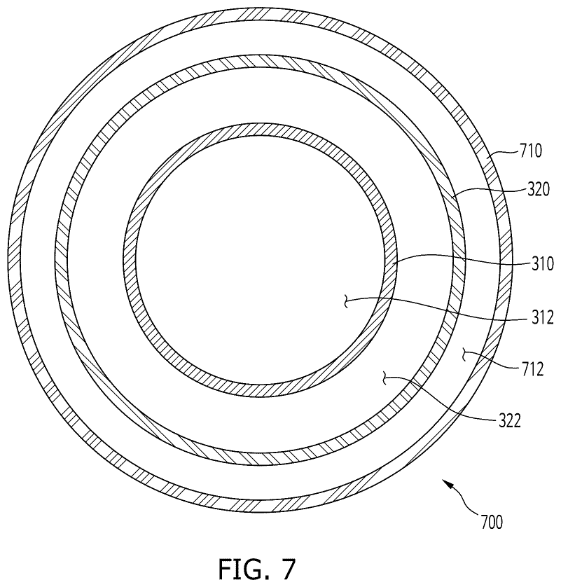

FIG. 7 is a cross-sectional view of an example of a precursor supply line 700. The precursor supply line 700 may correspond to the precursor supply line 140 of FIGS. 1 to 4. For example, precursor may flow through an inner space 312 of the inner pipe 310 of the precursor supply line 700 from the precursor supply apparatus 110 to the reaction chamber 120. In addition, fluid may be supplied along the fluid supply line 150 to a first space 322 between the first outer pipe 320 and an inner pipe 310 of the precursor supply line 700 through the first connection 330, and fluid may flow through the first space 322 between the first outer pipe 320 and the inner pipe 310 of the precursor supply line 700 to be supplied to the fluid recovery line 160 through the second connection 340.

The precursor supply line 700 may further include a second outer pipe 710 spaced apart from the first outer pipe 320 and disposed to surround the first outer pipe 320. A second space 712 between the first outer pipe 320 and the second outer pipe 710 may be in a vacuum state. Alternatively, a thermal insulating material may be disposed in the second space 712. For example, the thermal insulating material may include at least one of silica wool, mineral wool, or aerogel.

The second outer pipe 710 may include at least one of stainless steel (STS) and hastelloy. For example, the second outer pipe 710 may include at least one of STS 304, STS 316, and hastelloy.

The precursor supply line 700 may be disposed in the environment at room temperature. In this case, the second space 712 in the vacuum state or the second space 712 with the thermal insulating material disposed therein may reduce or prevent heat exchange through the outer circumference of the first outer pipe 320. Accordingly, the second space 712 in the vacuum state or the second space 712 with the thermal insulating material disposed therein may help to maintain a constant temperature of the fluid flowing through the first space 322 between the inner pipe 310 and the first outer pipe 320.

As described above, the fluid flowing through the first space 322 may be in contact with the outer circumference of the inner pipe 310. By maintaining a constant temperature of the fluid flowing through the first space 322, a constant temperature may be maintained inside the inner pipe 310. Accordingly, the temperature of the precursor flowing through the inner space 312 of the inner pipe 310 may be maintained at a constant temperature.

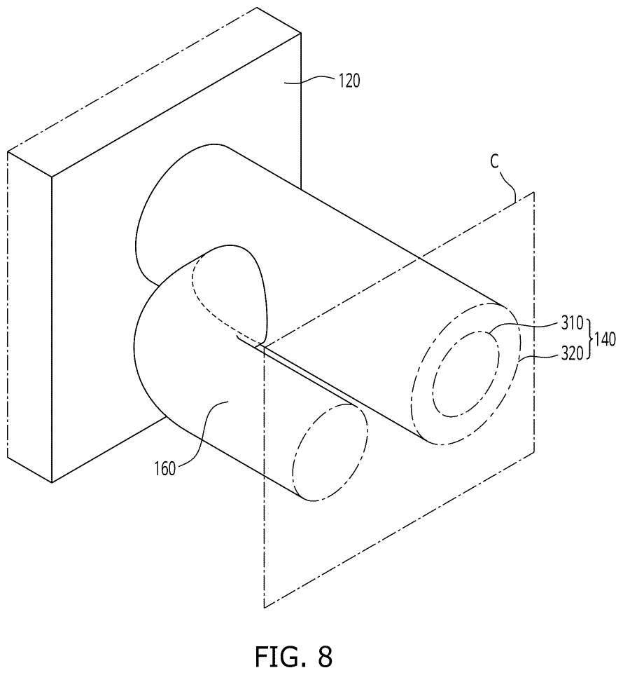

FIG. 8 is a view illustrating an example of the precursor supply line 140 and the fluid recovery line 160. FIG. 8 may show a cross-section taken along the cutting line C crossing the precursor supply line 140 and the fluid recovery line 160 shown in FIG. 1. A cross-section of the inner pipe 310 and a cross-section of the first outer pipe 320 may be illustrated in this cross-sectional view.

The fluid recovery line 160 may be branched off from the first outer pipe 320 of the precursor supply line 140. The fluid recovery line 160, branched and extended, may pass next to the precursor supply line 140. In this case, the fluid flowing along the fluid recovery line 160 may flow toward the fluid tank. If the fluid recovery line 160 passes parallel to the precursor supply line 140, the flow direction of the fluid flowing along the fluid recovery line may be a direction substantially opposite to the flow direction of the precursor flowing along the inner pipe 310.

FIG. 8 illustrates an aspect in which the fluid recovery line 160 is disposed parallel to the precursor supply line 140 while being spaced apart by a predetermined distance. However, aspects are not limited to the above. For example, the fluid recovery line 160 may be in contact with the precursor supply line 140. As another example, the fluid recovery line 160 may be spaced apart from the precursor supply line 140, but not parallel to the precursor supply line 140.

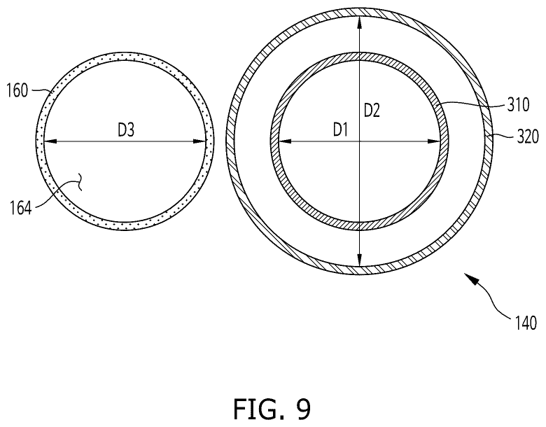

FIG. 9 shows cross-sectional views of the precursor supply line 140 and the fluid recovery line 160. FIG. 9 may illustrate cross-sections taken along the cutting line C of FIG. 8 and viewed from the front. An inner space 164 of the fluid recovery line 160 is a passage through which the fluid flows and the fluid may flow in a direction toward the fluid tank.

The fluid recovery line 160 may include at least one of stainless steel (STS) and hastelloy. For example, the fluid recovery line 160 may include at least one of STS 304, STS 316, and hastelloy.

Referring to FIG. 9, the cross-section of the fluid recovery line 160 may be approximately circular. A diameter D3 of the cross-section of the fluid recovery line may be greater than the diameter D1 of the cross-section of the inner pipe and smaller than the diameter D2 of the cross-section of the first outer pipe 320. For example, the diameter of the cross-section of the inner pipe 310 may be about ¾ inches, the diameter of the cross-section of the first outer pipe may be about 1 inch, and the diameter of the first outer pipe 320 may be about 5/4 inches, but aspects are not limited thereto.

In FIG. 9, it is illustrated that the fluid recovery line 160 is disposed together with the precursor supply line 140 of FIG. 5, but aspects are not limited thereto. For example, the fluid recovery line 160 may be disposed together with the precursor supply line 600 of FIG. 6 or with the precursor supply line 700 of FIG. 7.

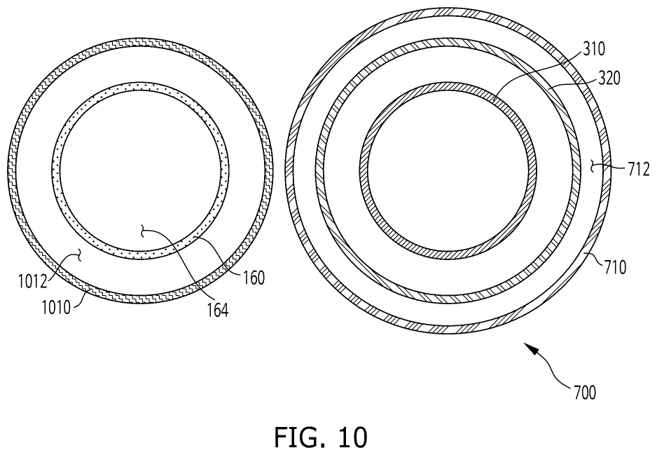

FIG. 10 shows cross-sectional views of the precursor supply line 700, the fluid recovery line 160, and a third outer pipe 1010. In FIG. 10, a description overlapping the precursor supply line 700 described with reference to FIG. 7 is not repeated.

The precursor supply system may include the third outer pipe 1010 spaced apart from the fluid recovery line 160 and disposed to surround the fluid recovery line 160. A third space 1012 between the fluid recovery line 160 and the third outer pipe 1010 may be in a vacuum state. Alternatively, a thermal insulating material may be disposed in the third space 1012.

The third outer pipe 1010 may include at least one of stainless steel (STS) and hastelloy. For example, the third outer pipe 1010 may include at least one of STS 304, STS 316, and hastelloy.

Together with the precursor supply line 700, the fluid recovery line 160 (or the third outer pipe 1010 including the fluid recovery line 160) may be disposed in the environment at room temperature. In this case, the third space 1012 in the vacuum state or the third space 1012 with the thermal insulating material disposed therein may reduce or prevent heat exchange through the outer circumference of the fluid recovery line 160. Accordingly, the third space 1012 in the vacuum state or the third space 1012 with the thermal insulating material disposed therein may help to maintain the constant temperature of the fluid flowing along the fluid recovery line 160.

In FIG. 10, it is illustrated that the fluid recovery line 160 and the third outer pipe 1010 are disposed together with the precursor supply line 700 of FIG. 7, but aspects are not limited thereto. For example, the fluid recovery line 160 and the third outer pipe 1010 may be disposed together with the precursor supply line 140 of FIG. 5 or the precursor supply line 600 of FIG. 6.

The second outer pipe 710 and the third outer pipe 1010 may be integrally implemented as one pipe. In this case, the inner pipe 310, the first outer pipe 320, and the fluid recovery line 160 may be positioned in one integrated pipe.

FIG. 11 is a flowchart 1100 provided to explain an example of a method for controlling at least one of the pump and the heater. The method for controlling at least one of the pump (e.g., the pump 154 in FIG. 1) or the heater (e.g., the heater 132 in FIG. 1) may be performed by the controller (e.g., the controller 170 in FIG. 1).

The method for controlling at least one of the pump or the heater may be initiated by receiving at least one of the first temperature value, the second temperature value, and the third temperature value, at S1110. The first temperature value may be generated by sensing the temperature of the fluid flowing along the fluid supply line (e.g., the fluid supply line 150) by the first temperature sensor (e.g., the first temperature sensor 152 of FIG. 1). The second temperature value may be generated by sensing the temperature of the fluid flowing along the fluid recovery line (e.g., the fluid recovery line 160) by the second temperature sensor (e.g., the second temperature sensor 162 of FIG. 1). The third temperature value may be generated by sensing the temperature of the fluid in the fluid tank (e.g., the fluid tank 130) by the third temperature sensor (e.g., the third temperature sensor 134 of FIG. 1).

The controller (e.g., the controller 170) may determine whether to control the temperature associated with the fluid based on at least one of the first temperature value, the second temperature value, and the third temperature value, at S1120. For example, the controller (e.g., the controller 170) may determine whether to control the temperature of the fluid flowing along the fluid supply line (e.g., the fluid supply line 150) based on the first temperature value. As another example, the controller (e.g., the controller 170) may determine whether to control the temperature of the fluid flowing along the fluid recovery line (e.g., the fluid recovery line 160) based on the second temperature value. As another example, the controller (e.g., the controller 170) may determine whether to control the temperature of the fluid contained in the fluid tank (e.g., the fluid tank 130) based on the third temperature value. The controller (e.g., the controller 170) may determine whether to control the temperature of the fluid flowing between the first outer pipe (e.g., the first outer pipe 320) and the inner pipe (e.g., the inner pipe 310) in the precursor supply line (e.g., the precursor supply line 140, the precursor supply line 600, or the precursor supply line 700) based on at least one of the first temperature value, the second temperature value, and the third temperature value. The controller (e.g., the controller 170) may determine whether to control the temperature of the fluid flowing between the first outer pipe (e.g., the first outer pipe 320) and the inner pipe (e.g., the inner pipe 310) in the precursor supply line (e.g., the precursor supply line 140, the precursor supply line 600, or the precursor supply line 700) based on two or more of the first, second, or third temperature values.

The controller (e.g., the controller 170) may control at least one of the pump (e.g., the pump 154) and the heater (e.g., the heater 132) based on the result of determination, at S1130. For example, the controller (e.g., the controller 170) may increase the temperature of the fluid contained in the fluid tank (e.g., the fluid tank 130) by increasing the output of the heater (e.g., the heater 132). The temperature of the fluid supplied to the fluid supply line (e.g., the fluid supply line 150) may be increased by increasing the temperature of the fluid contained in the fluid tank (e.g., the fluid tank 130). Additionally, since the fluid sequentially flows along the fluid supply line (e.g., the fluid supply line 150), between the first outer pipe (e.g., the first outer pipe 320) and the inner pipe (e.g., the inner pipe 310), and along the fluid recovery line (e.g., the fluid recovery line 160), the temperature of the fluid flowing between the first outer pipe (e.g., the first outer pipe 320) and the inner pipe (e.g., the inner pipe 310) and/or along the fluid recovery line (e.g., the fluid recovery line 160) may also rise.

The controller (e.g., the controller 170) may control a flow rate of the fluid supplied by the pump (e.g., the pump 154). For example, the controller (e.g., the controller 170) may increase or decrease the flow rate of the fluid supply line (e.g., the fluid supply line 150) by increasing or decreasing the flow rate of the fluid supplied by the pump (e.g., the pump 154). If the flow rate of the fluid supply line (e.g., the fluid supply line 150) is increased, the fluid flowing along the fluid supply line (e.g., the fluid supply line 150) may flow sequentially and relatively quickly between the first outer pipe (e.g., the first outer pipe 320) and the inner pipe (e.g., the inner pipe 310) and along the fluid recovery line (e.g., the fluid recovery line 160). In this case, the temperature difference between the fluid entering between the first outer pipe (e.g., the first outer pipe 320) and the inner pipe (e.g., the inner pipe 310), and the fluid exiting between the first outer pipe (e.g., the first outer pipe 320) and the inner pipe (e.g., the inner pipe 310) may be reduced. For example, the temperature difference between the fluid entering the first space 322 at the first connection 330 and the fluid exiting the first space 322 at the second connection 340 may be reduced.

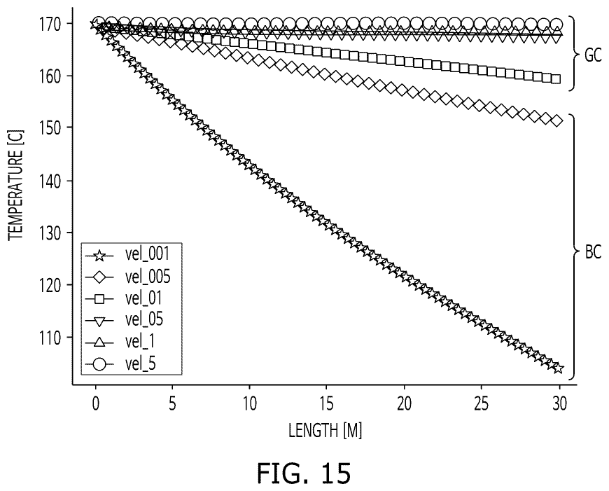

A temperature change of the fluid flowing between the first outer pipe (e.g., the first outer pipe 320) and the inner pipe (e.g., the inner pipe 310) according to the velocity of the fluid will be described below with reference to FIG. 15.

As described above, the controller (e.g., the controller 170) may control at least one of the pump (e.g., the pump 154) or the heater (e.g., the heater 132) to determine a target fluid to be at least one of the fluid flowing along the fluid supply line (e.g., the fluid supply line 150), the fluid flowing in the first space 322 between the first outer pipe (e.g., the first outer pipe 320) and the inner pipe (e.g., the inner pipe 310), the fluid flowing along the fluid recovery line (e.g., the fluid recovery line 160), or the fluid contained in the fluid tank (e.g., the fluid tank 130), and adjust the temperature of the target fluid to the target temperature.

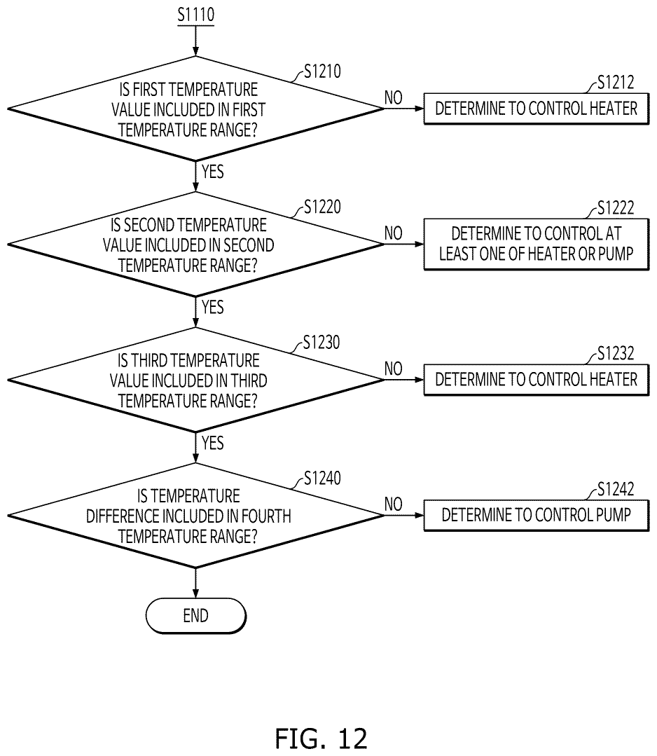

FIG. 12 is a flowchart provided to explain an example of the method for controlling at least one of the pump (e.g., the pump 154) and the heater (e.g., the heater 132). With reference to FIG. 12, an aspect of processes of performing operations S1120 and S1130 of FIG. 11 will be described in detail.

The controller (e.g., the controller 170) may determine whether the first temperature value is included in a first temperature range (e.g., a predetermined first temperature range), at S1210. The controller (e.g., the controller 170) may determine to control the heater (e.g., the heater 132) in response to determining that the first temperature value is not included in the first temperature range, at S1212. For example, the controller (e.g., the controller 170) may increase or decrease the temperature of the fluid contained in the fluid tank (e.g., the fluid tank 130) by increasing or decreasing the output of the heater (e.g., the heater 132). The fluid at the increased or decreased temperature may be supplied to the fluid supply line (e.g., the fluid supply line 150), increasing or decreasing the temperature of the fluid flowing along the fluid supply line (e.g., the fluid supply line 150).

The controller (e.g., the controller 170) may determine whether the second temperature value is included in a second temperature range (e.g., a predetermined second temperature range), at S1220. The controller (e.g., the controller 170) may determine to control at least one of the heater (e.g., the heater 132) and the pump (e.g., the pump 154) in response to determining that the second temperature value is not included in the second temperature range, at S1212. For example, the controller (e.g., the controller 170) may increase or decrease the temperature of the fluid contained in the fluid tank (e.g., the fluid tank 130) by increasing or decreasing the output of the heater (e.g., the heater 132). In addition, by increasing or decreasing the flow rate of the fluid supplied by the pump (e.g., the pump 154), the controller (e.g., the controller 170) may increase or decrease the velocity of the fluid in the fluid supply line (e.g., the fluid supply line 150), the space between the first outer pipe (e.g., the first outer pipe 320) and the inner pipe (e.g., the inner pipe 310), and the fluid recovery line (e.g., the fluid recovery line 160). For example, if the fluid having an increased or decreased temperature is supplied to the fluid supply line (e.g., the fluid supply line 150) and the velocity of the fluid is increased, the temperature of the fluid flowing along the fluid recovery line (e.g., the fluid recovery line 160) may be increased or decreased.

The controller (e.g., the controller 170) may determine whether the third temperature value is included in a third temperature range (e.g., a predetermined third temperature range), at S1230. The controller (e.g., the controller 170) may determine to control the heater (e.g., the heater 132) in response to determining that the third temperature value is not included in the third temperature range, at S1232. For example, the controller (e.g., the controller 170) may increase or decrease the temperature of the fluid contained in the fluid tank (e.g., the fluid tank 130) by increasing or decreasing the output of the heater (e.g., the heater 132).

The controller (e.g., the controller 170) may determine whether a temperature difference value, that is, a difference between the first temperature value and the second temperature value, is included in a fourth temperature range (e.g., a predetermined fourth temperature range), at S1240. The controller (e.g., the controller 170) may determine to control the pump (e.g., the pump 154) in response to determining that the temperature difference value is not included in the fourth temperature range, at S1242. For example, by increasing or decreasing the flow rate of the fluid supplied by the pump (e.g., the pump 154), the controller (e.g., the controller 170) may increase or decrease the velocity of the fluid in the fluid supply line (e.g., the fluid supply line 150), the space (e.g., the first space 322) between the first outer pipe (e.g., the first outer pipe 320) and the inner pipe (e.g., inner pipe 310), and the fluid recovery line (e.g., the fluid recovery line 160). As the velocity of the fluid increases, the temperature difference value may decrease, and conversely, as the velocity of the fluid decreases, the temperature difference value may increase.

In FIG. 12, operations S1210 and S1212, operations S1220 and S1222, operations S1230 and S1232 and operations S1240 and S1242 are shown in order, but aspects are not limited thereto. For example, each of the operations S1210, S1220, S1230, and S1240 may be performed in a different order, individually, or some operations may be omitted.

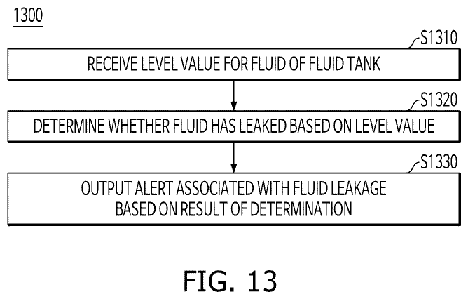

FIG. 13 is a flowchart 1300 provided to explain an example of a method for outputting an alert associated with fluid leakage. The method for outputting the alert associated with the fluid leakage may be performed by the controller (e.g., the controller 170).

The method for outputting the alert associated with the fluid leakage may be initiated by receiving a level value for the fluid in the fluid tank (e.g., the fluid tank 130), at S1310. The level value may indicate the amount of fluid contained in the fluid tank (e.g., the fluid tank 130). The level value may be provided to the controller (e.g., the controller 170) by the level sensor (e.g., the level sensor 136).

The controller (e.g., the controller 170) may determine whether the fluid leaks out based on the level value, at S1320. For example, the controller (e.g., the controller 170) may compare the level value with a level threshold (e.g., a predetermined level threshold, a level value in the fluid tank 130 sensed at a specific point in time, etc.). In response to determining that the level value is less than (or the equal to or less than) the level threshold, the controller (e.g., the controller 170) may determine that the fluid has leaked out of the fluid tank (e.g., the fluid tank 130). Alternatively, in response to determining that the level value is equal to or greater than (or greater than) the level threshold, the controller (e.g., the controller 170) may determine that the fluid has not leaked out of the fluid tank (e.g., the fluid tank 130).

The controller (e.g., the controller 170) may output an alert associated with the fluid leakage based on the result of determination, at S1330. For example, in response to determining that the fluid has leaked, the controller (e.g., the controller 170) may output the alert associated with the fluid leakage to an output device (e.g., a display, a speaker, etc.) connected to the controller (e.g., the controller 170). Additionally or alternatively, the controller (e.g., the controller 170) may stop the operation of the pump (e.g., the pump 154) to stop the circulation of the fluid. Alternatively, the controller (e.g., the controller 170) may cause the supply of the precursor to stop in the precursor supply system and/or the apparatus for semiconductor manufacturing. In addition, if it is determined that the fluid has not leaked, the controller (e.g., the controller 170) may not output the alert associated with fluid leakage.

The temperature of the fluid may be higher than room temperature. In this case, if the fluid leaks out, it may be dangerous for workers working on the apparatus for semiconductor manufacturing and/or on the precursor supply system. The apparatus for semiconductor manufacturing and/or the precursor supply system may prevent the worker from being exposed to danger through the method for outputting the alert associated with fluid leakage.

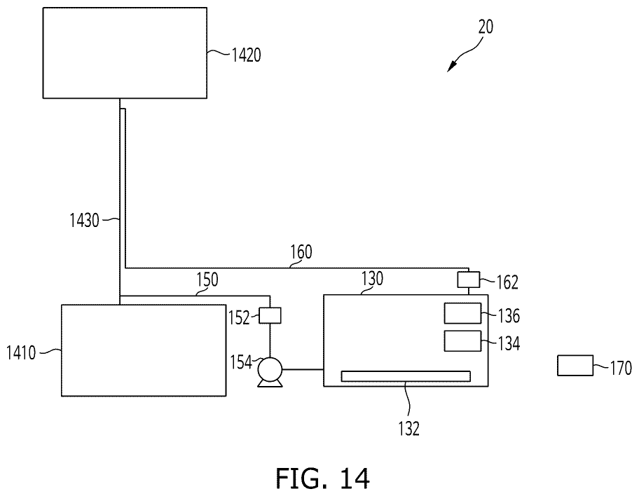

FIG. 14 is a schematic view provided to explain a manufacturing apparatus 20. The manufacturing apparatus 20 may be the apparatus for semiconductor manufacturing and may include a reaction chamber 1420 in which a semiconductor manufacturing process is performed, but aspects are not limited thereto.

The manufacturing apparatus 20 may include a fluid supply apparatus 1410 containing a first fluid and the reaction chamber 1420 configured to supply the first fluid. In addition, the manufacturing apparatus 20 may include a multilayer pipe 1430 that connects the fluid supply apparatus 1410 to the reaction chamber 1420, and includes the inner pipe configured to allow the first fluid to flow from the fluid supply apparatus 1410 to the reaction chamber 1420. That is, the first fluid of the fluid supply apparatus 1410 may be supplied to the reaction chamber 1420 through the multilayer pipe 1430. The multilayer pipe 1430 of FIG. 14 may be substantially the same as the precursor supply line 140 of FIGS. 1 to 5, the precursor supply line 600 of FIG. 6, or the precursor supply line 700 of FIG. 7, except that the first fluid may flow in the inner pipe of the multilayer pipe 1430 instead of a precursor.

The fluid supply apparatus 1410 may receive the first fluid in gaseous and/or liquid states. Additionally or alternatively, the fluid supply apparatus 1410 may include the precursors in gaseous, liquid and/or solid states of the first fluid, and generate the first fluid in gaseous and/or liquid states using the precursors of the first fluid. The fluid supply apparatus 1410 may supply the first fluid in gaseous and/or liquid states to the inner pipe of the multilayer pipe 1430.

The semiconductor manufacturing process may be performed in the reaction chamber 1420 using the supplied first fluid. For example, the first fluid may induce, trigger, and/or participate in the chemical reaction in at least some of the processes of semiconductor manufacturing. For example, the first fluid may be used for etching, deposition, etc. of the substrate that forms the semiconductor. For example, the first fluid may include a reactive gas, an inert gas, etc.

The multilayer pipe 1430 may include a first outer pipe spaced apart from an inner pipe in an outward direction and having the inner pipe disposed therein. In addition, the manufacturing apparatus 20 may include the fluid tank 130 containing a second fluid, the fluid supply line 150, and the fluid recovery line 160. The fluid tank 130 may also be referred to as the fluid supply apparatus. The second fluid may be substantially the same as the fluid described with reference to FIG. 1.

In addition, the structure in which the second fluid is sequentially circulated along the fluid supply line, between the first outer pipe and the inner pipe, and along the fluid recovery line may be substantially the same as the structure in which the fluid is circulated as described with reference to FIG. 1. For example, the fluid supply line 150 may merge into the first outer pipe and be configured to allow the second fluid to flow from the fluid tank 130 to the first outer pipe, and the fluid recovery line 160 may be branched off to the first outer pipe and be configured to allow the second fluid to flow from the first outer pipe to the fluid tank 130. As described above, the configurations of the manufacturing apparatus 20 other than the fluid supply apparatus 1410, the reaction chamber 1420, and the multilayer pipe 1430 may be understood based on the description above.

FIG. 15 shows simulation data of the fluid flowing between the first outer pipe and the inner pipe. The graph of FIG. 15 shows the data representing the temperature at each point of the precursor supply line or the multilayer pipe. The point of about 0 m in the X axis may correspond to a point at which the fluid enters between the first outer pipe and the inner pipe (e.g., first connection 330), and the point of about 30 m in the X axis may correspond to a point at which the fluid exits between the first outer pipe and the inner pipe (e.g., second connection 340). The temperature of the fluid entering between the first outer pipe and the inner pipe is about 170 degrees Celsius. vel_001, vel_005, vel_01, vel_05, vel_1, and vel_5 each indicate the velocities 0.01 m/s, 0.05 m/s, 0.1 m/s, 1 m/s, and 5 m/s of the fluid entering between the first outer pipe and the inner pipe, respectively.

Referring to the graph of FIG. 15, as the velocity of the fluid decreases, the extent of temperature decrease of the fluid flowing between the first outer pipe and the inner pipe increases. That is, the higher the velocity of the fluid, the smaller the difference between the temperature of the fluid entering between the first outer pipe and the inner pipe and the temperature of the fluid exiting between the first outer pipe and the inner pipe.

If the velocity of the fluid entering between the first outer pipe and the inner pipe is 0.1 m/s, 0.5 m/s, 1 m/s or 5 m/s (GC in FIG. 15), the temperature of the fluid discharged between the first outer pipe and the inner pipe is about 160 degrees Celsius or higher, and if the velocity of the fluid entering between the first outer pipe and the inner pipe is 0.01 m/s, 0.05 m/s or 0.1 m/s (BC in FIG. 15), the temperature of the fluid discharged between the first outer pipe and the inner pipe is lower than about 160 degrees Celsius. To maintain the precursor or fluid flowing inside the inner pipe at about 160 degrees Celsius, the velocity of the fluid entering between the first outer pipe and the inner pipe may be determined to be 0.1 m/s, 0.5 m/s, 1 m/s, or 5 m/s.

As described above, by increasing the circulation rate of the fluid (e.g., the velocity of the fluid supplied along the fluid supply line), the temperature of the fluid flowing between the first outer pipe and the inner pipe may be maintained at a constant temperature. Accordingly, it is easy to maintain a constant temperature of the precursor or the fluid flowing in the inner pipe.

1. A precursor supply system, comprising:
a precursor supply apparatus for containing a precursor;
a fluid tank for containing a fluid;
a precursor supply line connected to the precursor supply apparatus, and comprising an inner pipe configured to allow the precursor to flow therein, and a first outer pipe spaced apart from the inner pipe and disposed to surround the inner pipe;
a fluid supply line connected to the first outer pipe and configured to allow the fluid to flow therein from the fluid tank to the first outer pipe; and
a fluid recovery line connected to the first outer pipe and configured to allow the fluid to flow therein from the first outer pipe to the fluid tank,
wherein the fluid flowing along the fluid supply line flows through a first space formed between the first outer pipe and the inner pipe.

2. The precursor supply system according to claim 1,
wherein the precursor flows from the precursor supply apparatus to an external device along the inner pipe, and
wherein the fluid flows from the fluid tank to the external device through the first space.

3. The precursor supply system according to claim 1, wherein a first connection between the fluid supply line and the first outer pipe is positioned closer to the precursor supply apparatus than a second connection between the fluid recovery line and the first outer pipe.

4. The precursor supply system according to claim 1,
wherein the precursor supply line further comprises a second outer pipe spaced apart from the first outer pipe and disposed to surround the first outer pipe, and
wherein a second space between the second outer pipe and the first outer pipe is in a vacuum state.

5. The precursor supply system according to claim 1,
wherein the precursor supply line further comprises a second outer pipe spaced apart from the first outer pipe and disposed to surround the first outer pipe, and
wherein a thermal insulating material is disposed in a second space between the second outer pipe and the first outer pipe.

6. The precursor supply system according to claim 1, further comprising:
a third outer pipe spaced apart from the fluid recovery line and disposed to surround the fluid recovery line,
wherein a third space between the fluid recovery line and the third outer pipe is in a vacuum state.

7. The precursor supply system according to claim 1,
wherein each of a cross-section of the inner pipe and a cross-section of the first outer pipe is circular, and
wherein a diameter of the cross-section of the first outer pipe is 1.5 to 2 times a diameter of the cross-section of the inner pipe.

8. The precursor supply system according to claim 1, further comprising:
a heater configured to heat the fluid contained in the fluid tank; and
a controller configured to control the heater.

9. The precursor supply system according to claim 8, further comprising:
a first temperature sensor configured to sense a temperature of the fluid flowing along the fluid supply line and output a first temperature value; and
a second temperature sensor configured to sense a temperature of the fluid flowing along the fluid recovery line and output a second temperature value,
wherein the controller is configured to receive the first temperature value and the second temperature value.

10. The precursor supply system according to claim 9, further comprising:
a pump configured to supply the fluid contained in the fluid tank to the fluid supply line,
wherein the controller is configured to control a flow rate of the fluid supplied by the pump based on at least one of the first temperature value and the second temperature value.

11. The precursor supply system according to claim 9, further comprising:
a third temperature sensor configured to sense a temperature of the fluid contained in the fluid tank and output a third temperature value,
wherein the controller is configured to further receive the third temperature value and control the heater based on the first temperature value, the second temperature value, and the third temperature value.

12. The precursor supply system according to claim 11, wherein the controller is configured to compare a predetermined temperature range with at least one of the first temperature value, the second temperature value, and the third temperature value, and control a heat output of the heater in response to determining at least one of the first temperature value, the second temperature value, and the third temperature value is not included within the predetermined temperature range.

13. The precursor supply system according to claim 8, further comprising:
a level sensor configured to sense a level of the fluid contained in the fluid tank and output a level value,
wherein the controller is configured to further receive the level value, and output an alert associated with fluid leakage based on the level value.

14. The precursor supply system according to claim 1, wherein the fluid comprises at least one of silicone oil, water vapor, mineral oil, and synthetic oil.

15. An apparatus for semiconductor manufacturing, comprising:
a first fluid supply apparatus for containing a first fluid;
a second fluid supply apparatus for containing a second fluid;
a reaction chamber configured to be supplied with the first fluid therein;
a multilayer pipe connecting the first fluid supply apparatus to the reaction chamber and comprising an inner pipe configured to allow the first fluid to flow from the first fluid supply apparatus to the reaction chamber, and a first outer pipe spaced apart from the inner pipe in an outward direction and having the inner pipe disposed therein;
a fluid supply line merging into the first outer pipe and configured to allow the second fluid to flow from the second fluid supply apparatus to the first outer pipe;
a fluid recovery line branched off from the first outer pipe and configured to allow the second fluid to flow from the first outer pipe to the second fluid supply apparatus; and
a heater configured to heat the second fluid contained in the second fluid supply apparatus,
wherein the second fluid flows sequentially along the fluid supply line, between the first outer pipe and the inner pipe, and along the fluid recovery line.

16. The apparatus for semiconductor manufacturing according to claim 15,
wherein the multilayer pipe further comprises a second outer pipe spaced apart from the first outer pipe and disposed to surround the first outer pipe, and
wherein a space between the first outer pipe and the second outer pipe is in a vacuum state or a thermal insulating material is disposed in the space.

17. The apparatus for semiconductor manufacturing according to claim 15, further comprising:
a first temperature sensor configured to sense a temperature of the second fluid flowing along the fluid supply line and output a first temperature value;
a second temperature sensor configured to sense a temperature of the second fluid flowing along the fluid recovery line and output a second temperature value; and
a controller configured to receive the first temperature value and the second temperature value and control the heater.

18. The apparatus for semiconductor manufacturing according to claim 17, further comprising:
a pump configured to supply the second fluid contained in the second fluid supply apparatus to the fluid supply line,
wherein the controller is configured to control a flow rate of the second fluid supplied by the pump based on at least one of the first temperature value and the second temperature value.

19. The apparatus for semiconductor manufacturing according to claim 17, further comprising:
a third temperature sensor configured to sense a temperature of the second fluid contained in the second fluid supply apparatus and output a third temperature value,
wherein the controller is configured to further receive the third temperature value and control the heater based on the first temperature value, the second temperature value, and the third temperature value.

20. A precursor supply system, comprising:
a precursor supply apparatus for containing a precursor;
a fluid tank for containing a fluid;
a reaction chamber configured to be supplied with the precursor therein and perform a process for semiconductor manufacturing using the precursor;
a precursor supply line connected to the precursor supply apparatus, and including an inner pipe configured to allow the precursor to flow therein, and a first outer pipe spaced apart from the inner pipe and disposed to surround the inner pipe;
a fluid supply line connected to the first outer pipe and configured to allow the fluid to flow therein from the fluid tank to the first outer pipe;
a fluid recovery line connected to the first outer pipe and configured to allow the fluid to flow therein from the first outer pipe to the fluid tank;
a first temperature sensor configured to sense a temperature of the fluid flowing along the fluid supply line and output a first temperature value;
a second temperature sensor configured to sense a temperature of the fluid flowing along the fluid recovery line and output a second temperature value;
a third temperature sensor configured to sense a temperature of the fluid contained in the fluid tank and output a third temperature value;
a pump configured to supply the fluid contained in the fluid tank to the fluid supply line;
a heater configured to heat the fluid contained in the fluid tank; and
a controller configured to receive the first temperature value, the second temperature value, and the third temperature value and control at least one of the pump or the heater,
wherein the fluid flowing along the fluid supply line flows between the first outer pipe and the inner pipe.
